(19) United States
(12) Patent Application Publication
(10) Pub. No.: US 2025/0107135 A1
(43) Pub. Date: Mar. 27, 2025

(54) LATERAL-EXTENDED TRANSISTOR STRUCTURES FOR MINIMIZING SUBTHRESHOLD HUMP EFFECT

(71) Applicant: Cirrus Logic International Semiconductor Ltd., Edinburgh (GB)

(72) Inventors: Suman BANERJEE, Austin, TX (US); Claude ORTOLLAND, Austin, TX (US); Marc L. TARABBIA, Austin, TX (US); Kuen-Ting SHIU, Round Rock, TX (US); Jin TANG, Cupertino, CA (US)

(73) Assignee: Cirrus Logic International Semiconductor Ltd., Edinburgh (GB)

(21) Appl. No.: 18/434,993

(22) Filed: Feb. 7, 2024

Related U.S. Application Data
(60) Provisional application No. 63/585,249, filed on Sep. 26, 2023.

(51) Int. Cl. H01L 29/78; H01L 21/8234; H01L 27/02; H01L 29/06

(52) U.S. Cl. CPC H10D 30/601; H10D 62/126; H10D 84/013; H10D 84/038; H10D 89/10

(57) ABSTRACT

A semiconductor structure may include a substrate, an active region formed on the substrate, a gate region extended over the active region along a first direction parallel to a surface of the substrate, and a source region formed within the active region and adjacent to the gate region in a second direction parallel to the surface and perpendicular to the first direction. The source region may comprise a first subregion and a second subregion such that the second subregion is between the first subregion and the gate region. The first subregion may comprise a first width along the first direction and the second subregion may comprise a second width along the first direction. The first width may be less than the second width.

### RELATED APPLICATION

The present disclosure claims priority to U.S. Provisional Patent Application Ser. No. 63/585,249, filed Sep. 26, 2023, which is incorporated by reference herein in its entirety.

### FIELD OF DISCLOSURE

The present disclosure relates in general to semiconductor fabrication, and more particularly, to fabrication of and use of a lateral-extended (e.g., a cross-shaped) metal-oxide-semiconductor field-effect transistor (MOSFET) to minimize the subthreshold hump effect present in MOSFETs.

### BACKGROUND

Semiconductor device fabrication is a process used to create integrated circuits that are present in many electrical and electronic devices. It is a multiple-step sequence of photolithographic, mechanical, and chemical processing steps during which electronic circuits are gradually created on a wafer made of semiconducting material. For example, during semiconductor device fabrication, numerous discrete circuit components, including transistors, resistors, capacitors, inductors, and diodes may be formed on a single semiconductor die.

A transistor is a semiconductor device with many uses. Generally speaking, a transistor is a semiconductor device used to amplify or switch electronic signals and electrical power. It is composed of semiconductor material usually with at least three terminals for connection to an external circuit. Typically, a voltage or current applied to one pair of the transistor's terminals controls the current through another pair of terminals. One common type of transistor is a metal-oxide-semiconductor field-effect transistor (MOSFET). A typical MOSFET comprises an insulated gate, whose voltage determines the conductivity of the device as seen between two other non-gate terminals of the device, known as a drain terminal and source terminal. The MOSFET's ability to change conductivity with the amount of applied voltage allows it to be used for amplifying or switching electronic signals.

One particular problem of MOSFETs may be referred to as the subthreshold hump effect. The effect arises from shallow-trench isolation (STI) processes used in manufacturing of a MOSFET, in which a divot may appear along an edge of the active region of the MOSFET. The presence of such divot may cause non-uniformities along polysilicon and the STI edge and leads to parasitic transistors within the MOSFET having a lower threshold voltage than the core transistor of the MOSFET. Both the parasitic transistors and the core transistor may contribute to the total drain current of the MOSFET. Due to the smaller threshold voltage of the parasitic transistors, the resulting drain current versus gate-to-source voltage curve of the MOSFET may exhibit a “hump” (i.e., the “subthreshold hump”) at smaller gate-to-source voltages within the subthreshold region of the MOSFET. The subthreshold hump may lead to higher leakage currents, local mismatches, and undesirable noise behavior within an analog circuit. Accordingly, it may be desirable to reduce or eliminate this subthreshold hump effect.

### SUMMARY

In accordance with the teachings of the present disclosure, certain disadvantages and problems associated with existing approaches to manufacturing MOSFETs may be reduced or eliminated.

In accordance with embodiments of the present disclosure, a semiconductor structure may include a substrate, an active region formed on the substrate, a gate region extended over the active region along a first direction parallel to a surface of the substrate, and a source region formed within the active region and adjacent to the gate region in a second direction parallel to the surface and perpendicular to the first direction. The source region may comprise a first subregion and a second subregion such that the second subregion is between the first subregion and the gate region. The first subregion may comprise a first width along the first direction and the second subregion may comprise a second width along the first direction. The first width may be less than the second width.

In accordance with these and other embodiments of the present disclosure, an integrated circuit may include a substrate and a transistor over the substrate. The transistor may comprise an active region formed on the substrate, a gate region extended over the active region along a first direction parallel to a surface of the substrate, and a source region formed within the active region and adjacent to the gate region in a second direction parallel to the surface and perpendicular to the first direction. The source region may comprise a first subregion and a second subregion such that the second subregion is between the first subregion and the gate region. The first subregion may comprise a first width along the first direction and the second subregion may comprise a second width along the first direction. The first width may be less than the second width.

In accordance with these and other embodiments of the present disclosure, a semiconductor chip may include a substrate, a first active region having a first width along a first direction parallel to a surface of the substrate, a gate extended over the first active region along the first direction, and a second active region formed on the surface adjacent to the first oxide diffusion region and having a second width shorter than the first width along the first direction.

In accordance with these and other embodiments of the present disclosure, a method may comprise forming an active region on a substrate, forming a gate region extended over the active region along a first direction parallel to a surface of the substrate, and forming a source region within the active region and adjacent to the gate region in a second direction parallel to the surface and perpendicular to the first direction, wherein the source region comprises a first subregion and a second subregion such that the second subregion is between the first subregion and the gate region, the first subregion comprises a first width along the first direction and the second subregion comprises a second width along the first direction, and the first width is less than the second width.

In accordance with these and other embodiments of the present disclosure, a computer program product for implementing a semiconductor structure may comprise a substrate, an active region formed on the substrate, a gate region extended over the active region along a first direction parallel to a surface of the substrate, and a source region formed within the active region and adjacent to the gate region in a second direction parallel to the surface and perpendicular to the first direction, wherein the source region comprises a first subregion and a second subregion such that the second subregion is between the first subregion and the gate region, the first subregion comprises a first width along the first direction and the second subregion comprises a second width along the first direction, and the first width is less than the second width, the computer program product comprising a computer usable medium having computer readable code physically embodied therein, said computer program product further comprising computer readable program code for describing the semiconductor structure.

Technical advantages of the present disclosure may be readily apparent to one having ordinary skill in the art from the figures, description and claims included herein. The objects and advantages of the embodiments will be realized and achieved at least by the elements, features, and combinations particularly pointed out in the claims.

It is to be understood that both the foregoing general description and the following detailed description are explanatory examples and are not restrictive of the claims set forth in this disclosure.

### BRIEF DESCRIPTION OF THE DRAWINGS

A more complete understanding of the present embodiments and advantages thereof may be acquired by referring to the following description taken in conjunction with the accompanying drawings, in which like reference numbers indicate like features, and wherein:

FIG. 1 illustrates a top-down plan view of a conventional MOSFET, as is known in the art;

FIG. 2 illustrates a top-down plan view of a lateral-extended MOSFET, in accordance with embodiments of the present disclosure;

FIG. 3 illustrates an example equivalent circuit diagram of the lateral-extended MOSFET of FIG. 2, in accordance with embodiments of the present disclosure;

FIG. 4 illustrates a top-down plan view of the lateral-extended MOSFET of FIG. 2, with certain physical dimensions annotated, in accordance with embodiments of the present disclosure;

FIGS. 5A and 5B respectively illustrate a top-down plan view of the lateral-extended MOSFET of FIG. 2 and a cross-sectional side elevation view of the lateral-extended MOSFET of FIG. 2, in accordance with embodiments of the present disclosure;

FIGS. 6A and 6B respectively illustrate a top-down plan view of the lateral-extended MOSFET of FIG. 2 and another cross-sectional side elevation view of the lateral-extended MOSFET of FIG. 2, in accordance with embodiments of the present disclosure;

FIGS. 7A and 7B respectively illustrate a top-down plan view of the lateral-extended MOSFET of FIG. 2 and a further cross-sectional side elevation view of the lateral-extended MOSFET of FIG. 2, in accordance with embodiments of the present disclosure;

FIGS. 8A and 8B respectively illustrate a top-down plan view of the lateral-extended MOSFET of FIG. 2 and an additional cross-sectional side elevation view of the lateral-extended MOSFET of FIG. 2, in accordance with embodiments of the present disclosure;

FIG. 9 illustrates a top-down plan view of a tapered lateral-extended MOSFET, in accordance with embodiments of the present disclosure;

FIG. 10 illustrates a top-down plan view of a lateral-extended MOSFET having two gate subregions, in accordance with embodiments of the present disclosure;

FIGS. 11A, 11B, and 11C respectively illustrate a top-down plan view of the lateral-extended MOSFET of FIG. 2, a first cross-sectional side elevation view of the lateral-extended MOSFET of FIG. 2 during a first step of a fabrication process and a second cross-sectional side elevation view of the lateral-extended MOSFET of FIG. 2 during the first step of the fabrication process, in accordance with embodiments of the present disclosure;

FIGS. 12A and 12B respectively illustrate a top-down plan view of the lateral-extended MOSFET of FIG. 2 and a cross-sectional side elevation view of the lateral-extended MOSFET of FIG. 2 during a second step of the fabrication process, in accordance with embodiments of the present disclosure;

FIGS. 13A and 13B respectively illustrate a top-down plan view of the lateral-extended MOSFET of FIG. 2 and a cross-sectional side elevation view of the lateral-extended MOSFET of FIG. 2 during a third step of the fabrication process, in accordance with embodiments of the present disclosure;

FIGS. 14A and 14B respectively illustrate a top-down plan view of the lateral-extended MOSFET of FIG. 2 and a cross-sectional side elevation view of the lateral-extended MOSFET of FIG. 2 during an alternative third step of the fabrication process, in accordance with embodiments of the present disclosure;

FIGS. 15A and 15B respectively illustrate a top-down plan view of the lateral-extended MOSFET of FIG. 2 and a cross-sectional side elevation view of the lateral-extended MOSFET of FIG. 2 during a fourth step of the fabrication process, in accordance with embodiments of the present disclosure;

FIGS. 16A and 16B respectively illustrate a top-down plan view of the lateral-extended MOSFET of FIG. 2 and a cross-sectional side elevation view of the lateral-extended MOSFET of FIG. 2 during a fifth step of the fabrication process, in accordance with embodiments of the present disclosure;

FIG. 17 illustrates a block diagram of an example circuit design system, in accordance with embodiments of the present disclosure;

FIG. 18 illustrates a block diagram of a synthesis software tool, in accordance with embodiments of the present disclosure; and

FIG. 19 illustrates a flow chart of an example method for synthesizing an integrated circuit design with a MOSFET shown and described herein, in accordance with the present disclosure.

### DETAILED DESCRIPTION

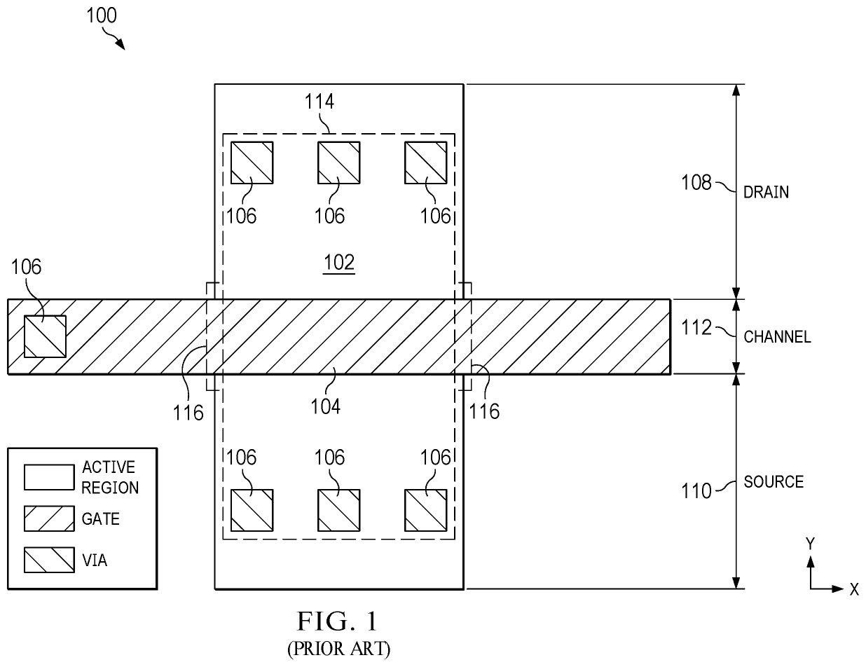

FIG. 1 illustrates a top-down plan view of a conventional MOSFET 100, as is known in the art. As shown in FIG. 1, MOSFET 100 may include an active region 102 formed in a semiconductor substrate (e.g., silicon wafer), with a gate 104 formed over a portion of active region 102, and one or more vias 106 formed upon active region 102 and gate 104, thus splitting active region 102 into a drain region 108, a source region 110, and a channel region 112. In MOSFET 100, the width of channel region 112 (e.g., in the x-axis depicted in FIG. 1) may be approximately equal to the width of drain region 108 and/or the width of source region 110. MOSFET 100 may be formed using an STI process, thus resulting in, in addition to a core transistor 114, parasitic transistors 116 being present in divots resulting from the STI process, as described in the Background section.

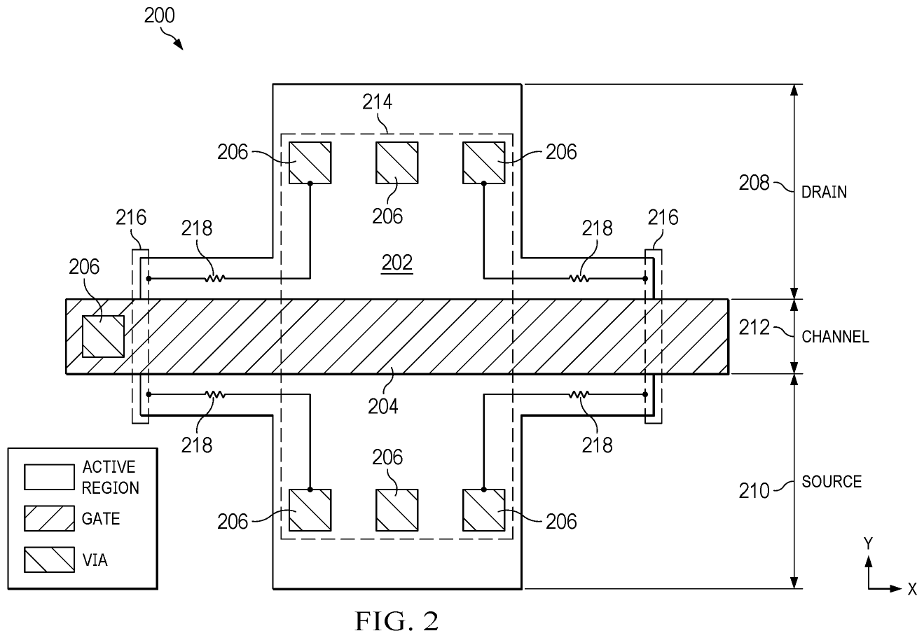

FIG. 2 illustrates a top-down plan view of a lateral-extended MOSFET 200, in accordance with embodiments of the present disclosure. As shown in FIG. 2, MOSFET 200 may include a lateral-extended active region 202 formed in a semiconductor substrate (e.g., silicon wafer), with a gate 204 formed over active region 202, and one or more vias 206 formed upon active region 202 and gate 204, thus splitting active region 202 into a drain region 208, a source region 210, and a channel region 212.

MOSFET 200 may be formed using an STI process, thus resulting in, in addition to a core transistor 214, parasitic transistors 216 being present in divots resulting from the STI process. However, as compared to MOSFET 100, the parasitic transistors 216 of MOSFET 200 may be laterally spaced from core transistor 214 (e.g., as compared to the spacing between parasitic transistors 116 and core transistor 114 in MOSFET 100). This additional lateral distance resulting from lateral-extended active region 202 may introduce additional resistance (as compared to MOSFET 100) between the source region 210/drain region 208 and the channel region 212 of parasitic transistors 216, as shown by the annotation of resistors 218 on FIG. 2.

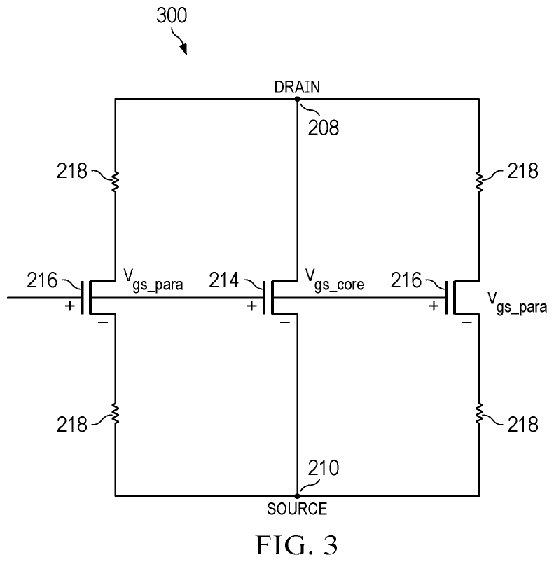

FIG. 3 illustrates an example equivalent circuit diagram 300 of lateral-extended MOSFET 200, in accordance with embodiments of the present disclosure. As shown in FIG. 3, lateral-extended MOSFET 200 can be represented by core transistor 214 in parallel with each of two combinations of a resistor 218, parasitic transistor 216, and another resistor 218 in series, thus showing that the paths of parasitic transistors 216 include resistances (represented by resistors 218) which may not be present in conventional MOSFET 100. Thus, the gate-source voltages V_{GS_PARA} across parasitic transistors 216 may be smaller than the gate-source voltage V_{GS_CORE} across core transistor 214, meaning the drain current of MOSFET 200 contributed by parasitic transistors 216 may be reduced (e.g., as compared to the drain current of MOSFET 100 contributed by parasitic transistors 116), which may reduce (e.g., as compared to MOSFET 100) or eliminate the subthreshold bump in MOSFET 200.

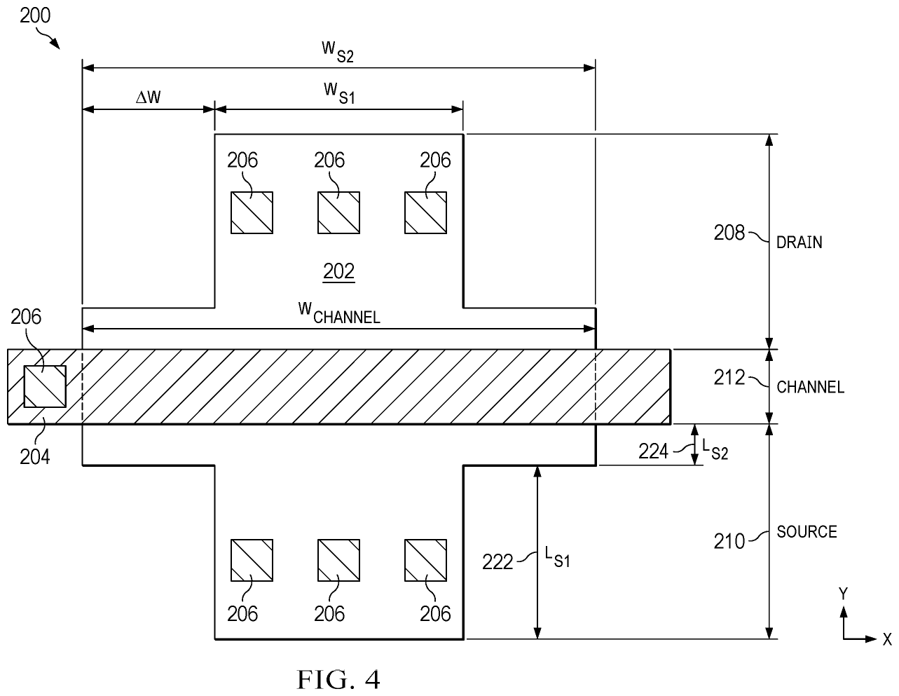

FIG. 4 illustrates a top-down plan view of lateral-extended MOSFET 200, with certain physical dimensions annotated, in accordance with embodiments of the present disclosure. As shown in FIG. 4, source region 210 may comprise at least two subregions 222 and 224, wherein subregion 222 is further away from channel region 212 as compared to subregion 224. As shown in FIG. 4, subregion 222 may have a width W_{S1} and a length L_{S1}, while subregion 224 may have a width W_{S2}>W_{S1} and a length L_{S2}. In some cases, subregion 224 may be in contact with channel region 212, and thus width W_{S2} may be equal to a width W_{CHANNEL} of channel region 212, while W_{S1}<W_{CHANNEL}.

In some embodiments, to provide for maximum resistance in the path of parasitic transistors 216, L_{S1}≥L_{S2}. Further, in some embodiments, a distance ΔW representing a distance in the x-axis between the edges of subregions 222 and 224 may be sized such that ΔW≥L_{S2}>0, in order to provide enough squares of physical layout for a given sheet resistance (e.g., ohms per layout square) of active region 202. For example, in some instances, for a typical silicide sheet resistance of about 10 ohms/square, distance ΔW may need to be several times the length L_{S2} (e.g., ΔW/Lₛ₂≥3.0) in order to provide a sufficient number of squares to incur enough resistance in the path of parasitic transistors 216. As another example, in these and other instances, based on a doping density of active region 202, distance ΔW and/or length L_{S2} may need to be greater than the active region's surface depletion width (e.g., such as ΔW≥0.05 μm and/or ΔL_{S2}≥0.05 μm, using presently-existing process technology specifications and device sizes) in order to separate the channel region of a parasitic transistor 216 from the edge of subregion 222.

In some embodiments, to provide for maximum resistance in the path of parasitic transistors 216, subregion 224 must be more resistive along the x-direction than subregion 222 along the y-direction. For example, either or both of Wₛ₂/Lₛ₂≥Lₛ₁/Wₛ₁ or ΔW/Lₛ₂≥Lₛ₁/Wₛ₁ may be required to ensure that subregion 224 has more layout squares than subregion 222.

In these and other embodiments, to provide for maximum resistance in the path of parasitic transistors 216, subregion 224 must be more resistive along the x-direction than the entirety of source region 210 along the y-direction. For example, ΔW/Lₛ₂≥Lₛ₁/Wₛ₁+Lₛ₂/Wₛ₂ may be required to ensure that subregion 224 has more layout squares than the entirety of source region 210.

In some embodiments, drain region 208 may have its own subregions of similar or identical dimensions as those described above with respect to source region 210.

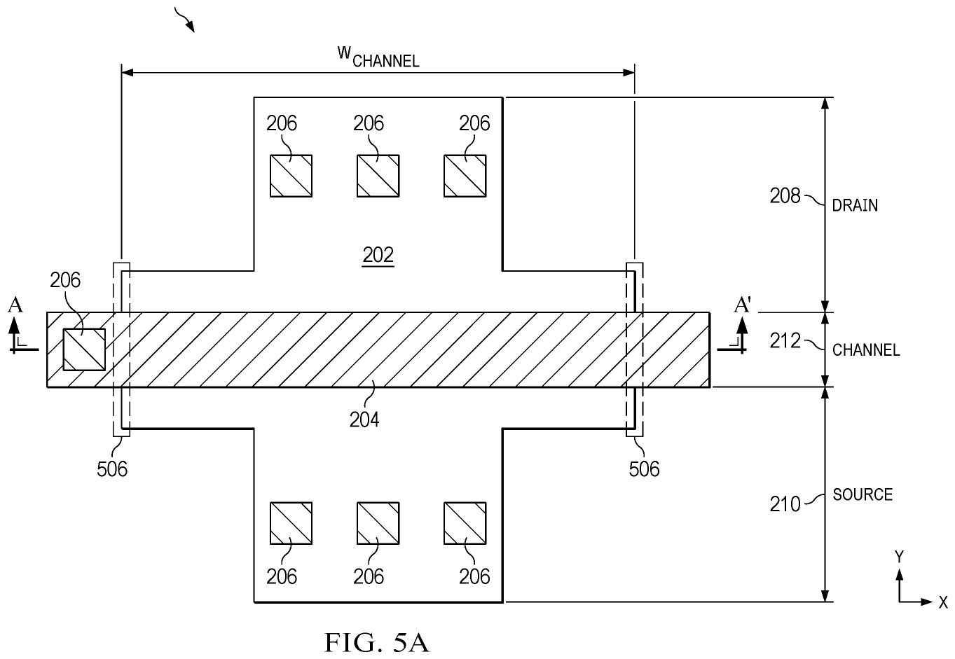

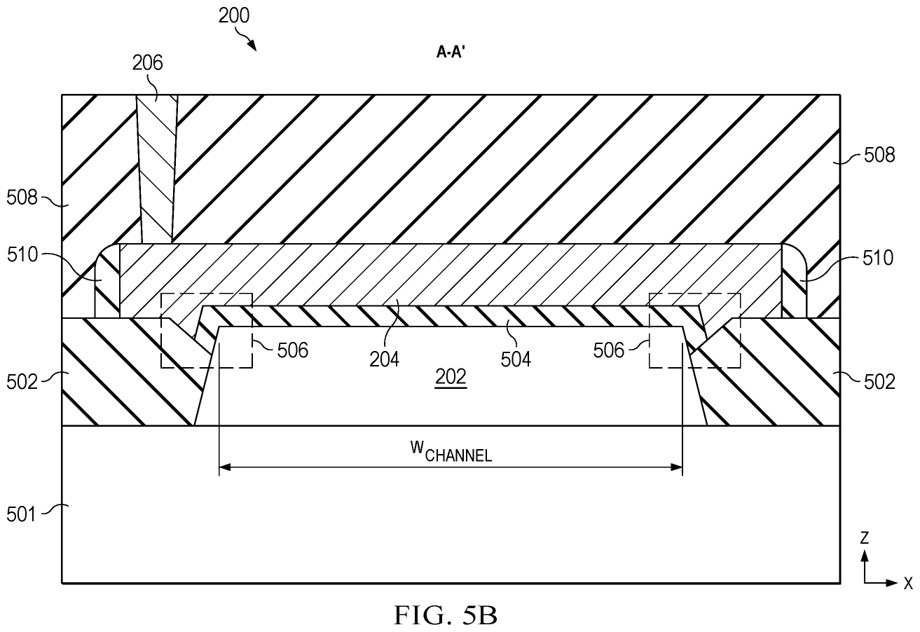

FIG. 5A illustrates a top-down plan view of lateral-extended MOSFET 200, and FIG. 5B illustrates a cross-sectional side elevation view of the lateral-extended MOSFET 200 taken along A-A′ of FIG. 5A, in accordance with embodiments of the present disclosure. Notably, FIG. 5B depicts STI being made of silicon oxide (SiO) 502 formed on a surface of a substrate 501 adjacent to channel region 212 of active region 202, which may leave divots 506 along edges of active region 202 in channel region 212. In some embodiments, substrate 501 and active region 202 can be made of a same material, such as silicon. FIG. 5B also depicts a gate oxide 504 present between the electrode of gate 204 and channel region 212, to provide dielectric insulation between gate 204 and channel region 212. FIG. 5B further depicts gate spacers 510 formed adjacent to gate 204, a dielectric layer 508 formed over gate 204 and gate spacers 510, and a via 206 formed within dielectric layer 508 to provide electrical connection to gate 204.

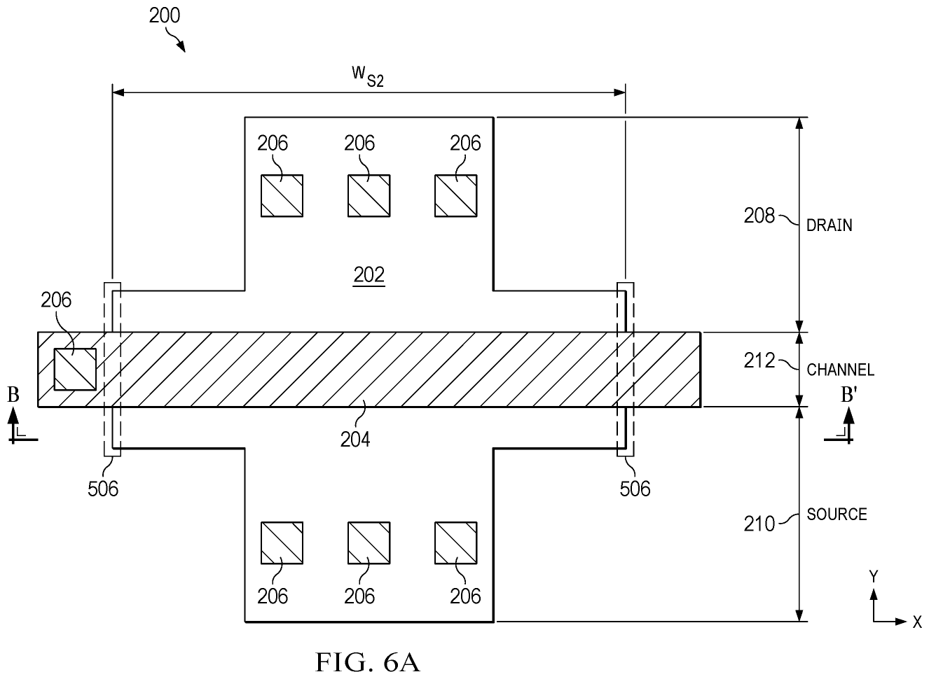

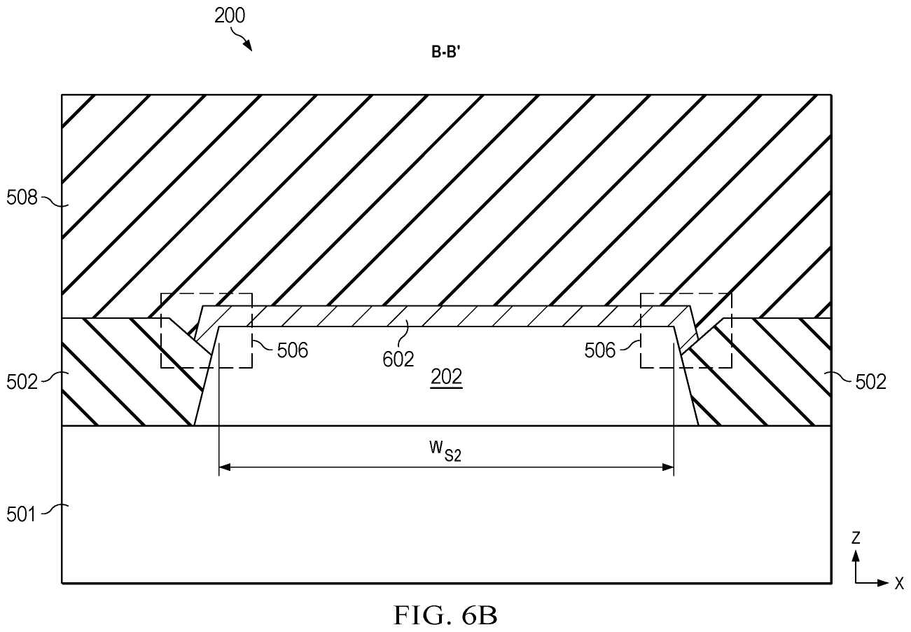

FIG. 6A illustrates a top-down plan view of lateral-extended MOSFET 200, and FIG. 6B illustrates a cross-sectional side elevation view of the lateral-extended MOSFET 200 taken along B-B′ of FIG. 6A, in accordance with embodiments of the present disclosure. As shown in FIG. 6B, a silicide layer 602 may be formed over source region 210 of active region 202.

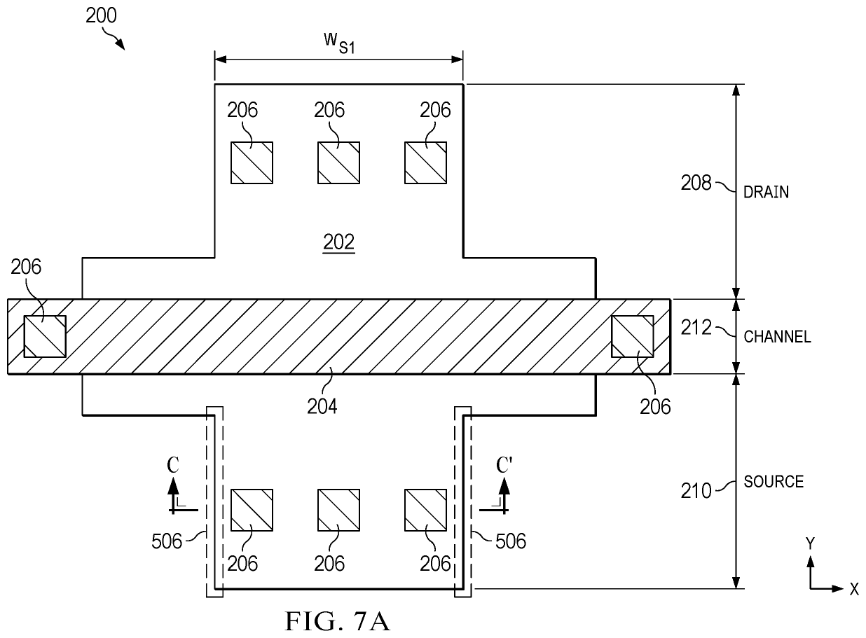

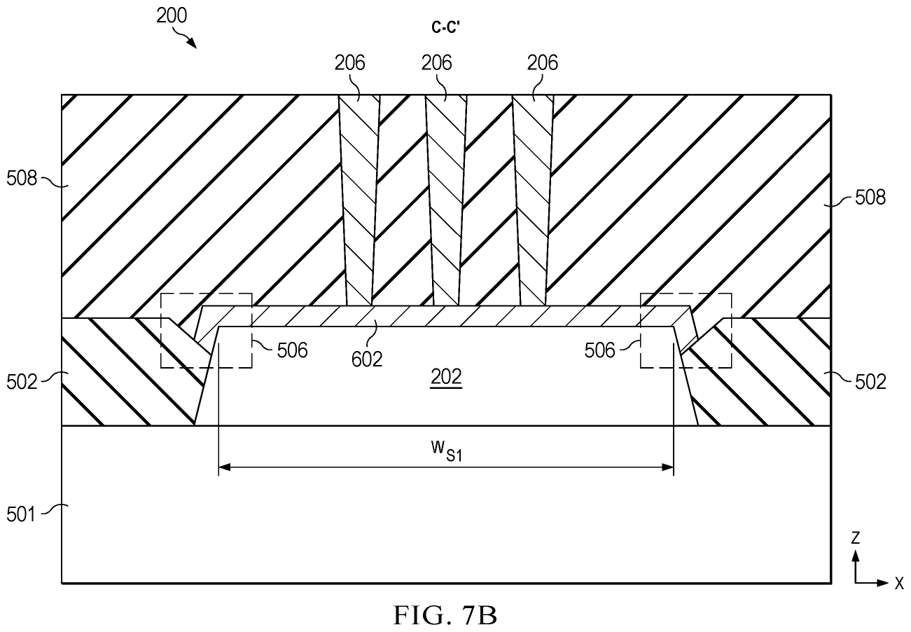

FIG. 7A illustrates a top-down plan view of lateral-extended MOSFET 200, and FIG. 7B illustrates a cross-sectional side elevation view of the lateral-extended MOSFET 200 taken along C-C′ of FIG. 7A, in accordance with embodiments of the present disclosure. As shown in FIG. 7B, silicide layer 602 may be formed over source region 210 of active region 202, and vias 206 may be formed within dielectric layer 508 to electrically couple to silicide layer 602 in order to provide electrical connection to channel region 212.

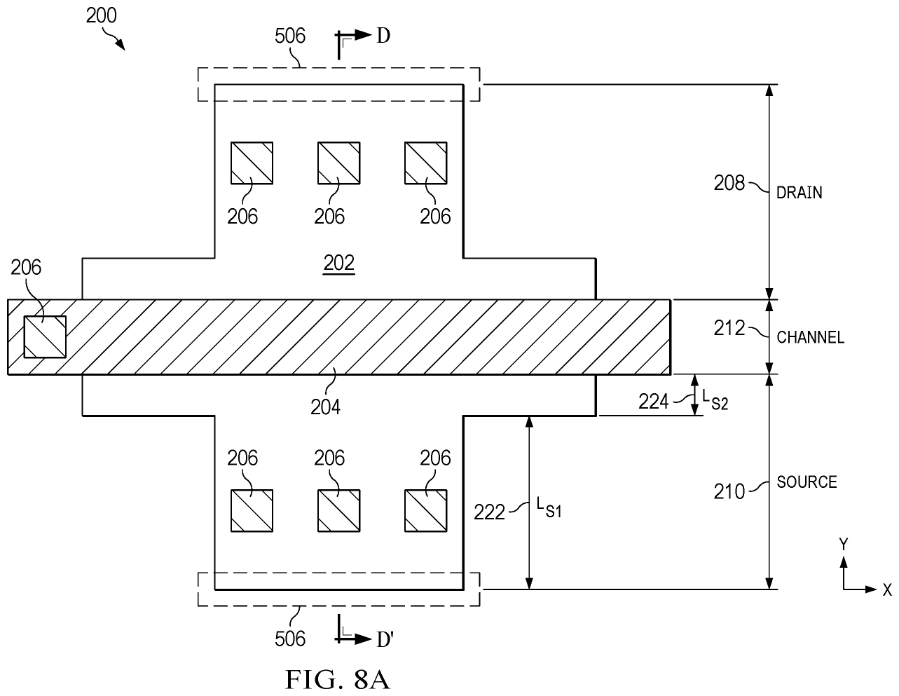

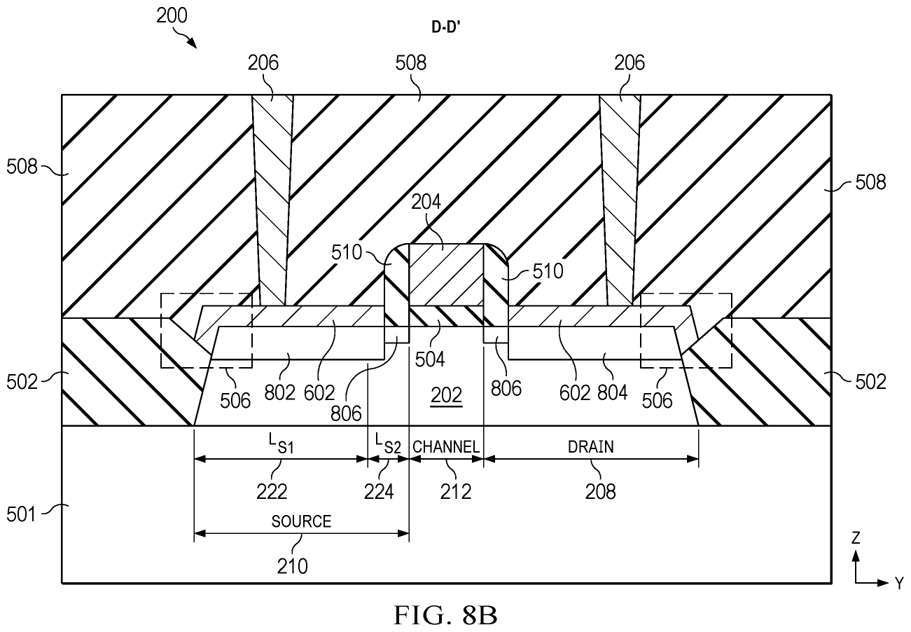

FIG. 8A illustrates a top-down plan view of lateral-extended MOSFET 200, and FIG. 8B illustrates a cross-sectional side elevation view of the lateral-extended MOSFET 200 taken along D-D′ of FIG. 8A, in accordance with embodiments of the present disclosure. As shown in FIG. 8B, gate oxide 504 may be present between the electrode of gate 204 and channel region 212, to provide dielectric insulation between gate 204 and channel region 212. FIG. 8B further depicts gate spacers 510 formed adjacent to gate 204 and silicide layers 602 formed over source region 210 and drain region 208. FIG. 8B additionally shows source doping 802 in source region 210 and drain doping 804 in drain region 208. FIG. 8B also shows dielectric layer 508 formed over gate 204, gate spacers 510, source region 210, and drain region 208, and vias 206 formed within dielectric layer 508 to provide electrical connection to source region 210 and drain region 208. Moreover, FIG. 8B depicts formation of lightly-doped drain (LDD) layer 806 under gate spacers 510.

In the various views depicted in FIGS. 5A-8B above, some portions of lateral-extended MOSFET 200 may not be shown for purposes of clarity and exposition.

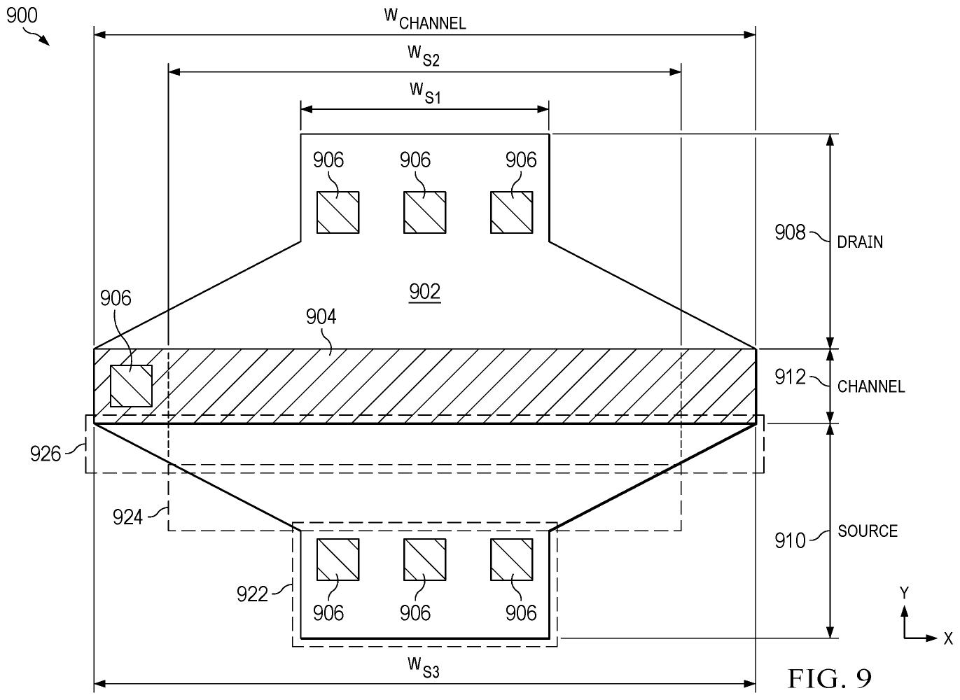

FIG. 9 illustrates a top-down plan view of a tapered lateral-extended MOSFET 900, in accordance with embodiments of the present disclosure. As shown in FIG. 9, MOSFET 900 may include a lateral-extended active region 902 formed in a semiconductor substrate (e.g., silicon wafer), with a gate 904 formed over the cross portion of active region 902, and one or more vias 906 formed upon active region 902 and gate 904, thus splitting active region 902 into a drain region 908, a source region 910, and a channel region 912.

MOSFET 900 may be similar in many respects to lateral-extended MOSFET 200, but different in that source region 910 may include three or more subregions 922, 924, and 926, for example wherein subregion 926 may be closer to channel region 912 than subregion 924, and subregion 924 may be closer to subregion 922. Although source region 910 is shown in FIG. 9 as having three subregions 922, 924, and 926 for the purposes of clarity and exposition, source region 910 may include four or more subregions.

As also shown in FIG. 9, in some embodiments, some subregions of source region 910 (e.g., subregions 924 and 926) may have a trapezoidal or tapered shape. For example, subregion 924 may have a width W_{S2} on one edge that tapers to a width W_{S1} of subregion 922, and subregion 926 may have a width W_{S3} on one edge that tapers to width W_{S2} of subregion 924. One advantage of such tapered shape is that such shape may avoid a sharp edge (e.g., 90° edge) between adjacent subregions and/or between a subregion (e.g., subregion 926) and channel region 912. Sharp 90° edges may cause a high localized electric field which may degrade a lifetime of MOSFET 900. In these and other embodiments, the subregion closest to channel region 912 (e.g., subregion 926) may have a width (e.g., width W_{S3}) on one edge equal to a width W_{CHANNEL} of channel region 912.

Otherwise, in some embodiments, the various features of tapered lateral-extended MOSFET 900 may be the same or similar to that of lateral-extended MOSFET 200. In these and other embodiments, drain region 908 may have its own subregions of similar or identical dimensions as those described above with respect to source region 910 and shown in FIG. 9.

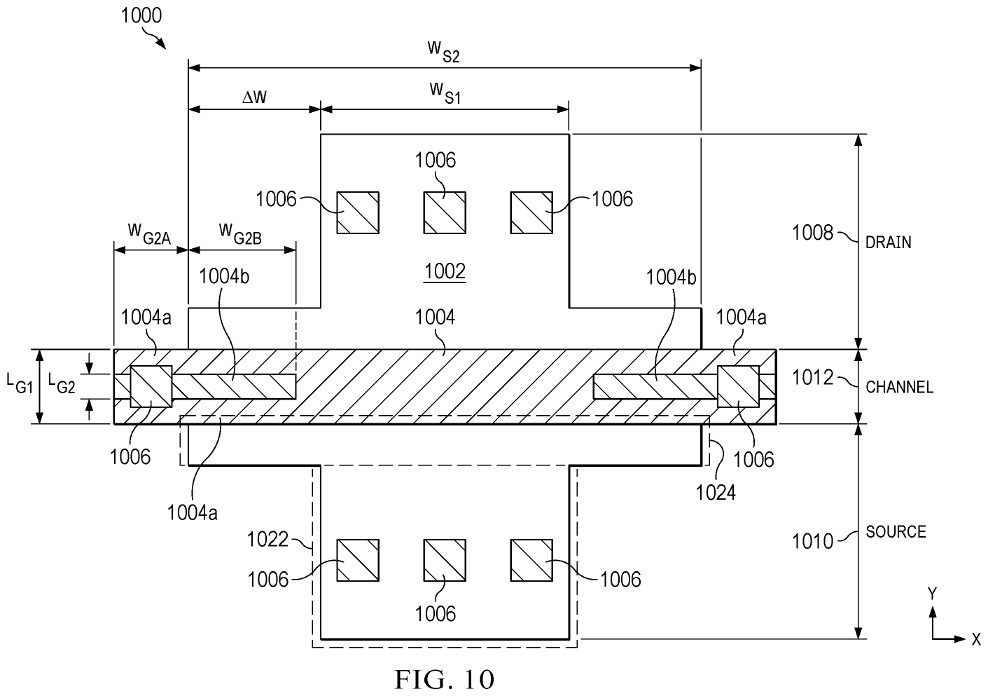

FIG. 10 illustrates a top-down plan view of a lateral-extended MOSFET 1000 having two gate subregions 1004a and 1004b, in accordance with embodiments of the present disclosure. As shown in FIG. 10, MOSFET 1000 may include a lateral-extended active region 1002 formed in a semiconductor substrate (e.g., silicon wafer), with a gate 1004 with two subregions 1004a and 1004b formed over active region 1002, and one or more vias 1006 formed upon active region 1002 and gate 1004, thus splitting active region 1002 into a drain region 1008, a source region 1010, and a channel region 1012. Similar to MOSFET 200, source region 1010 of MOSFET 1000 may have a plurality of subregions (e.g., subregions 1022 and 1024). In these and other embodiments, drain region 1008 may have its own subregions of similar or identical dimensions as those described above with respect to source region 1010 and shown in FIG. 10.

MOSFET 1000 may be similar in many respects to lateral-extended MOSFET 200, but different in that gate 1004 may include two or more subregions 1004a and 1004b, wherein gate subregion 1004b is formed vertically (e.g., in z-direction) over parasitic transistors of MOSFET 1000 and STI that is proximate to active region 1002, each gate subregion 1004a, 1004b having a different doping, thereby gate subregions 1004a and 1004b may have different work functions to provide different threshold capacitors for the core transistor of MOSFET 1000 and the parasitic transistors of MOSFET 1000. In some embodiments, the doping concentration of gate subregion 1004b may be less than that of gate subregion 1004a. In these and other embodiments, gate subregion 1004a and gate subregion 1004b may have different doping polarities. In these and other embodiments, a via 1006 may overlap both gate subregion 1004a and gate subregion 1004b in order to concurrently provide the same voltage to both gate subregion 1004a and gate subregion 1004b.

As shown in FIG. 10, gate subregion 1004b may overlap, along the x-direction, subregion 1024 of source region 1010 but may not overlap, along the x-direction, subregion 1022 of source region 1010. Further as shown in FIG. 10, gate subregion 1004a may have a length L_{G1} and gate subregion 1004b may have a length L_{G2} wherein L_{G1}≥L_{G2}. In addition, gate subregion 1004b may have a width which is the sum of a width W_{G2A} which is non-overlapping with active region 1002 and a width W_{G2B} which is overlapping with active region 1002. In some embodiments, W_{G2A}>0, and ΔW≥W_{G2B}, wherein ΔW represents a distance in the x-axis between the edges of subregions 1022 and 1024.

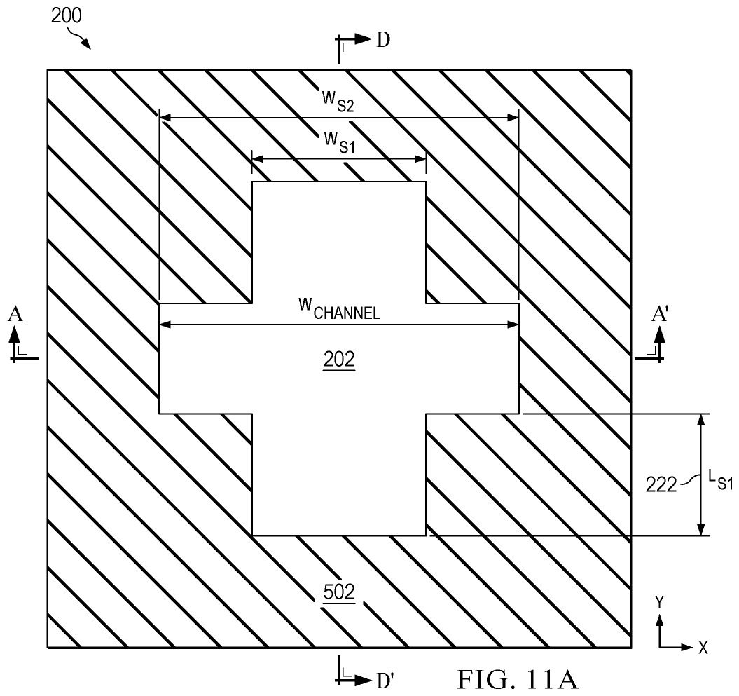

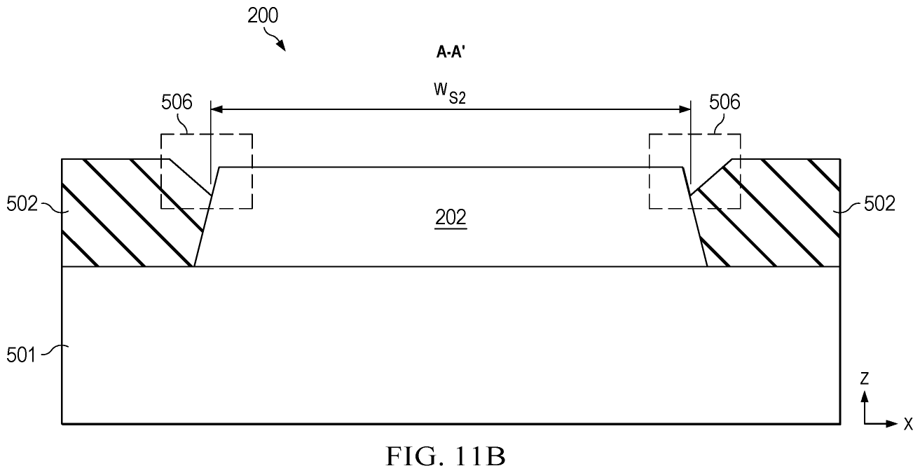

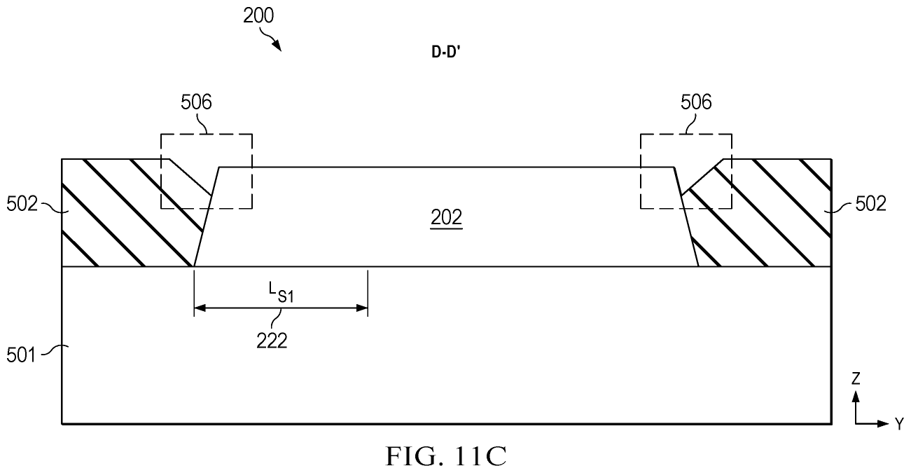

FIGS. 11A, 11B, and 11C respectively illustrate a top-down plan view of lateral-extended MOSFET 200, a first cross-sectional side elevation view of lateral-extended MOSFET 200 taken along A-A′ of FIG. 11A during a first step of a fabrication process and a second cross-sectional side elevation view of lateral-extended MOSFET 200 taken along D-D′ of FIG. 11A during the first step of the fabrication process, in accordance with embodiments of the present disclosure. As shown in FIGS. 11A-C, during such first step, lateral-extended active region 202 may be formed on a substrate (e.g., as forming an oxide diffusion (OD) region that includes n-type and/or p-type areas on substrate 501), and STI may be performed to form SiO 502 proximate to active region 202, leaving divots 506 between active region 202 and SiO 502. A step similar to this first step may also be used to fabricate MOSFET 1000.

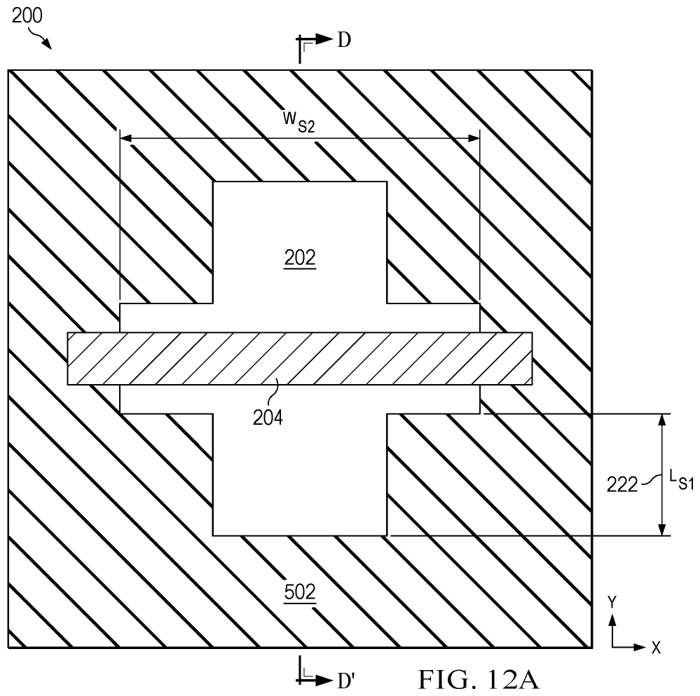

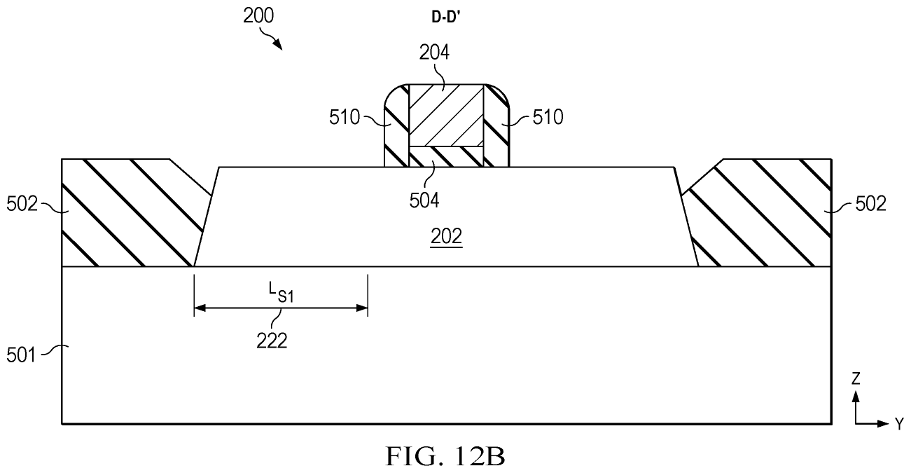

FIGS. 12A and 12B respectively illustrate a top-down plan view of lateral-extended MOSFET 200 and cross-sectional side elevation view of lateral-extended MOSFET 200 taken along D-D′ of FIG. 12A during a second step of the fabrication process, in accordance with embodiments of the present disclosure. As shown in FIGS. 12A and 12B, during such second step, a gate structure may be formed over the cross portion of active region 202, such gate structure including gate 204, gate oxide 504, and gate spacers 510. A step similar to this second step may also be used to fabricate MOSFET 1000.

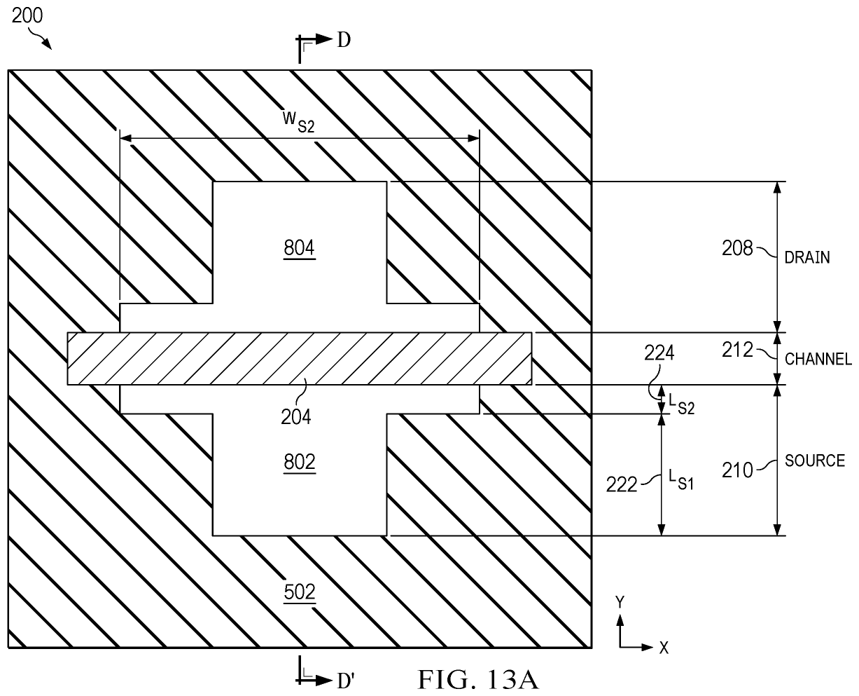

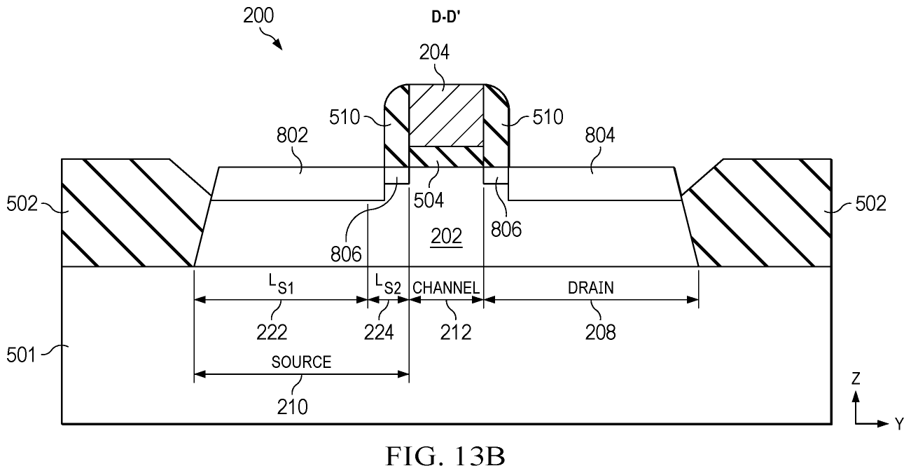

FIGS. 13A and 13B respectively illustrate a top-down plan view of lateral-extended MOSFET 200 and cross-sectional side elevation view of lateral-extended MOSFET 200 taken along D-D′ of FIG. 13A during a third step of the fabrication process, in accordance with embodiments of the present disclosure. As shown in FIGS. 13A and 13B, during such third step, source region 210 may be doped with source doping 802, drain region 208 may be doped with drain doping 804, and lightly-doped drain layer 806 may be formed on either side of gate 204.

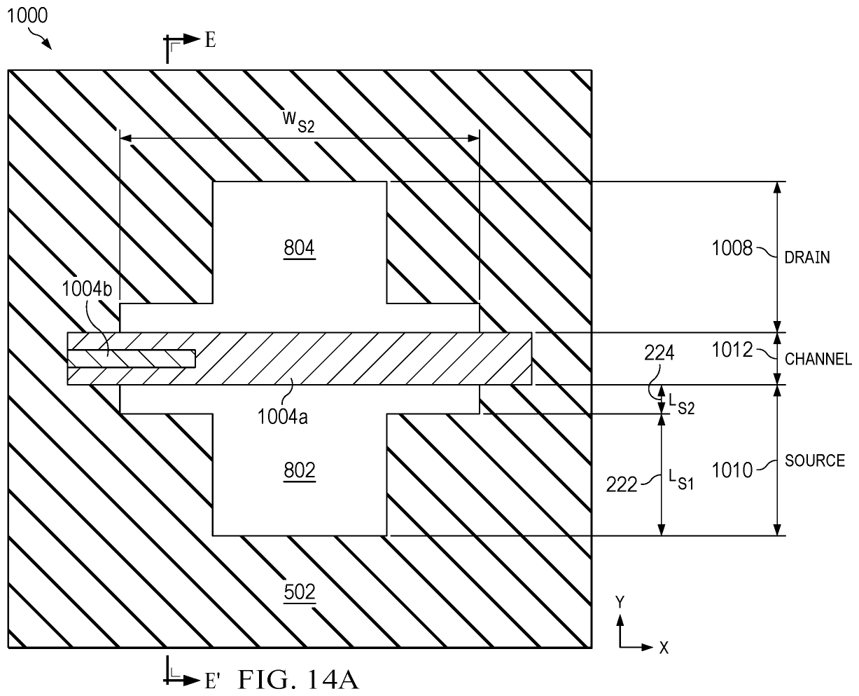

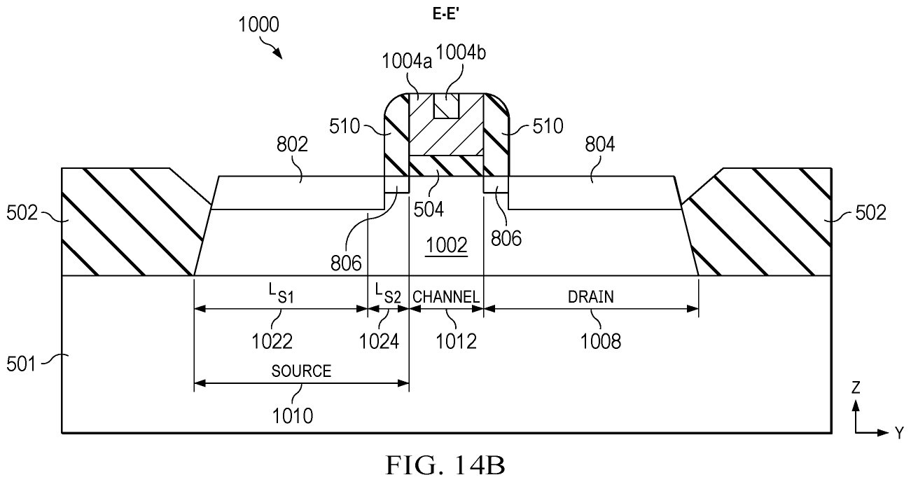

FIGS. 14A and 14B respectively illustrate a top-down plan view of lateral-extended MOSFET 1000 and cross-sectional side elevation view of lateral-extended MOSFET 1000 taken along E-E′ of FIG. 14A during an alternative third step of the fabrication process, in accordance with embodiments of the present disclosure. As shown in FIGS. 14A and 14B, during such alternative third step source region 1010 may be doped with source doping 802, drain region 1008 may be doped with drain doping 804, and lightly-doped drain layer 806 may be formed on either side of gate 1004. Concurrently with doping of source region 1010 and drain region 1008, gate subregion 1004b may also be formed. In some embodiments, gate subregion 1004b may be formed using a lightly-doped drain layer of an opposite polarity MOSFET on substrate 501. For example, MOSFET 1000 may be an n-channel MOSFET on substrate 501, where an implantation process that forms LDD layer of a p-channel MOSFET (not shown in FIGS. 14A and 14B) on substrate 501 may be used to form gate subregion 1004b of n-channel MOSFET 1000. Similarly, as another example, MOSFET 1000 may be a p-channel MOSFET on substrate 501, where an implantation process that forms LDD layer of an n-channel MOSFET (not shown in FIGS. 14A and 14B) on substrate 501 may be used to form gate subregion 1004b of p-channel MOSFET 1000. Such alternative third step may be used in lieu of the third step described above in order to fabricate MOSFET 1000.

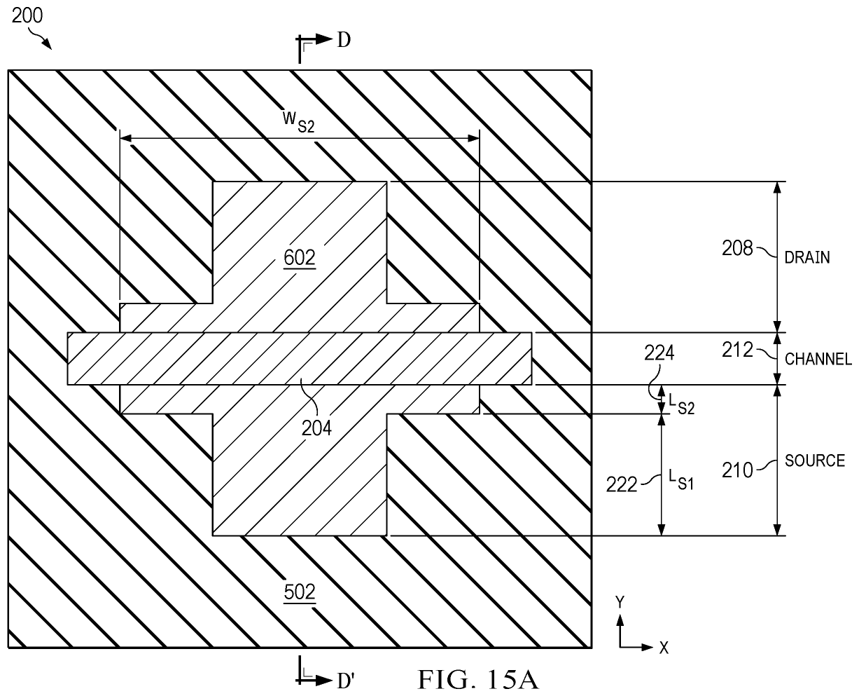

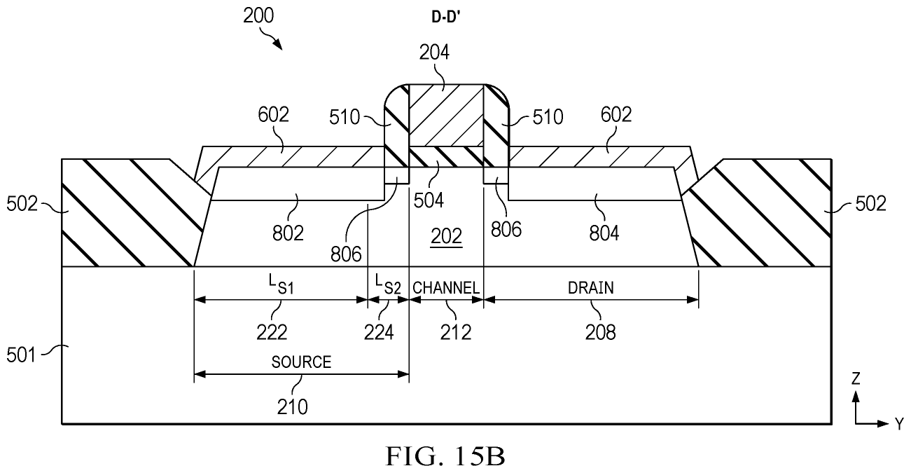

FIGS. 15A and 15B respectively illustrate a top-down plan view of lateral-extended MOSFET 200 and cross-sectional side elevation view of lateral-extended MOSFET 200 taken along D-D′ of FIG. 15A during a fourth step of the fabrication process, in accordance with embodiments of the present disclosure. As shown in FIGS. 15A and 15B, during such fourth step, silicide 602 may be formed over source region 210 and drain region 208. A step similar to this fourth step may also be used to fabricate MOSFET 1000.

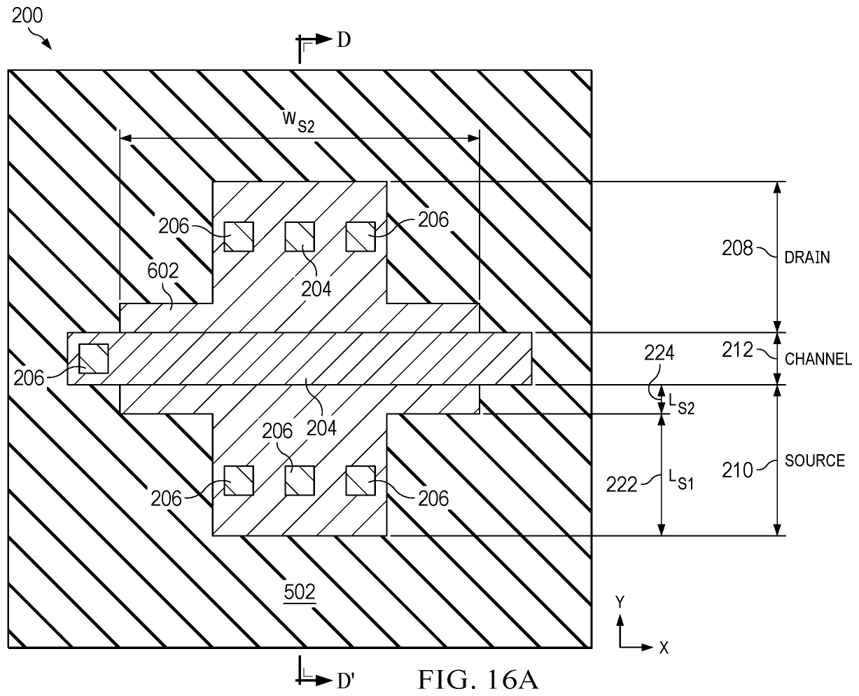

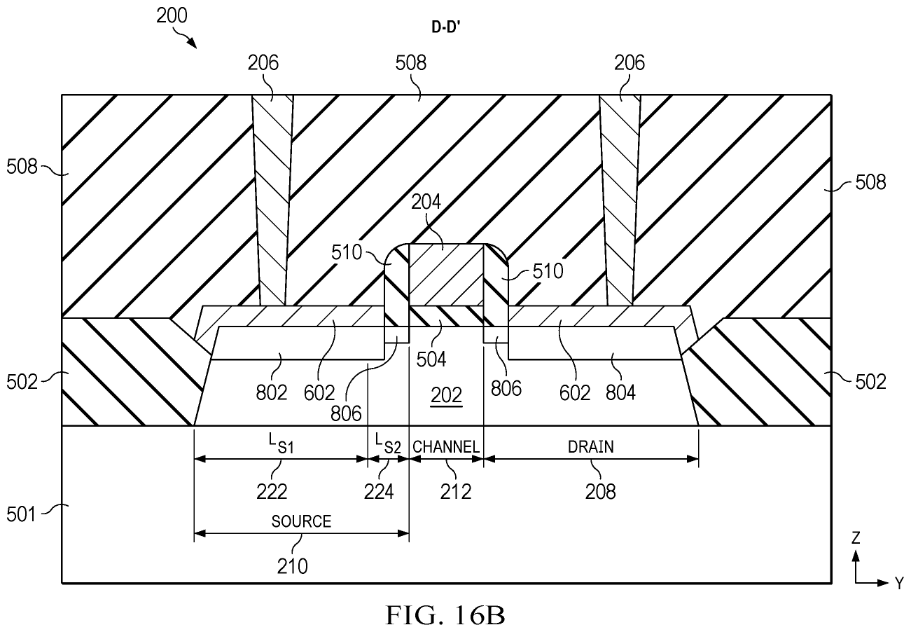

FIGS. 16A and 16B respectively illustrate a top-down plan view of lateral-extended MOSFET 200 and cross-sectional side elevation view of lateral-extended MOSFET 200 taken along D-D′ of FIG. 16A during a fifth step of the fabrication process, in accordance with embodiments of the present disclosure. As shown in FIGS. 16A and 16B, during such fifth step, vias 206 may be formed to provide electrical coupling to gate 204, source region 210, and drain region 208, and dielectric 508 may be formed over components of MOSFET 200 such that vias are formed within dielectric 508. A step similar to this fifth step may also be used to fabricate MOSFET 1000.

Although FIGS. 11A-16B show specific steps in fabrication of MOSFET 200 and MOSFET 1000, steps other than those depicted may be used in fabrication of MOSFET 200 and MOSFET 1000. Further, steps similar or identical to those shown with respect to FIGS. 11A-16B may also be used in the fabrication of MOSFET 900.

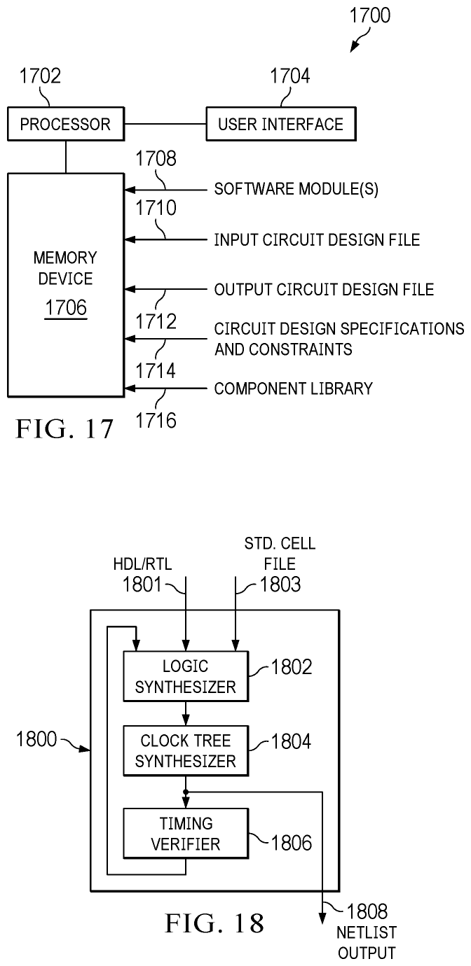

FIG. 17 illustrates a block diagram of an example circuit design system 1700, in accordance with embodiments of the present disclosure. Circuit design system 1700 may be capable of receiving and synthesizing, analyzing, and/or optimizing an initial circuit design that includes one or more of MOSFETs 200, 900, and/or 1000. Circuit design system 1700 may comprise any computing device, such as a computer that has a processor 1702, a user interface 1704, and a memory device 1706.

Processor 1702 may include any system, device, or apparatus configured to interpret and/or execute program instructions and/or process data, and may include, without limitation, a microprocessor, microcontroller, digital signal processor (DSP), application specific integrated circuit (ASIC), or any other digital or analog circuitry configured to interpret and/or execute program instructions and/or process data. In some embodiments, processor 1702 may interpret and/or execute program instructions and/or process data stored in memory device 1706 and/or another component of circuit design system 1700.

Memory device 1706 may be communicatively coupled to processor 1702 and may include any system, device, or apparatus configured to retain program instructions and/or data for a period of time (e.g., computer-readable media). Memory device 1706 may include random access memory (RAM), read-only memory (ROM), electrically erasable programmable read-only memory (EEPROM), flash memory, magnetic storage, opto-magnetic storage, or any suitable selection and/or array of volatile or non-volatile memory that retains data after power to circuit design system 1700 is turned off. Memory device 1706 may store different types of instructions and/or data, including, but not limited to software module(s) 1708 including executable instructions that may be executed by processor 1702 (e.g., circuit design synthesis, analysis and/or optimization tools) to control processor 1702 in performing its various operations, an input circuit design file 1710, an output circuit design file 1712, circuit design specifications and constraints 1714, a component library 1716, and/or other data, information, or instructions. One or more of input circuit design file 1710, circuit design specifications and constraints 1714, and component library 1716 may include data and information for defining MOSFETs 200, 900, and/or 1000.

User interface 1704 may comprise any instrumentality or aggregation of instrumentalities by which a user may interact with circuit design system 1700. For example, user interface 1704 may permit a user to input data and/or instructions into circuit design system 1700, and/or otherwise manipulate circuit design system 1700 and its associated components (e.g., via keyboard, mouse, trackpad, or other pointing device). User interface 1704 may also permit circuit design system 1700 to communicate data to a user, e.g., by way of a display device.

FIG. 18 illustrates a block diagram of an example synthesis software tool 1800, in accordance with embodiments of the present disclosure. Synthesis software tool 1800 may be stored as computer-readable instructions in memory device 1706 and readable and executable by the processor 1702 of circuit design system 1700. Synthesis software tool 1800 may comprise a logic synthesizer module 1802, a clock tree synthesizer module 1804, and a timing verifier 1806. Logic synthesizer module 1802 may receive a high-level description language (HDL) or register transfer level (RTL) circuit description 1801 and a standard cell technology file 1803. Functional logic may be generated from standard cell technology file 1803 by logic synthesizer module 1802, including the various MOSFETs 200, 900, and/or 1000 that are in the data paths of circuit description 1801. Standard cell technology file 1803 may include data and information for characterizing MOSFETs 200, 900, and/or 1000 as one or more standard cells. Clock tree synthesizer module 1804 may generate clock tree paths in the integrated circuit from a clock source to the clock inputs of the various elements including the various MOSFETs 200, 900, and/or 1000 in the data paths. The timing verifier module 1806 may receive a netlist including data paths and clock tree paths of the integrated circuit design to verify that timing specifications are satisfied with the given logical design of the integrated circuit. Timing verifier module 1806 may verify that the timing specifications of the logical design are in fact met to output a netlist 1808. Netlist 1808 may be sent to a foundry for manufacturing of the integrated circuit described by netlist 1808.

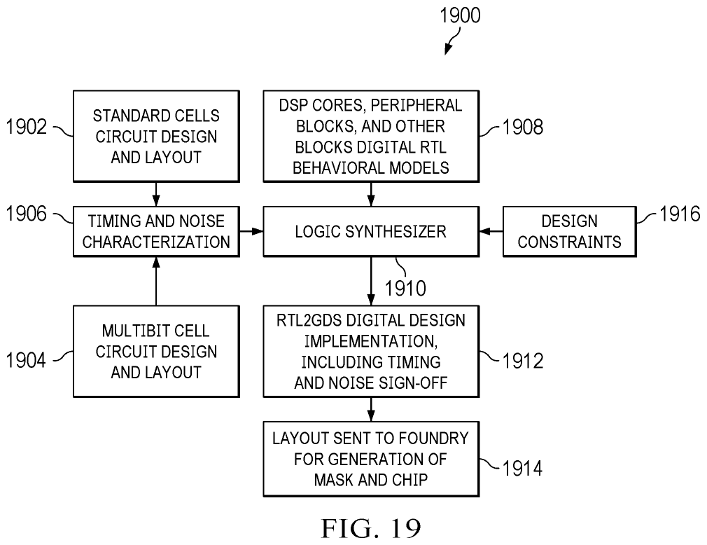

FIG. 19 illustrates a flow chart of an example method 1900 for synthesizing an integrated circuit design with MOSFETs 200, 900, and/or 1000, in accordance with the present disclosure. Method 1900 may be embodied in instructions that are stored in memory device 1706 of circuit design system 1700 and read and executed by processor 1702. For example, method 1900 may be implemented by synthesis software tool 1800. In accordance with method 1900, at block 1902, a standard cell circuit design and layout for an integrated circuit design may be provided to a timing and noise characterization block 1906, and at block 1904, multi-bit cell circuit design and layout for the integrated circuit design that incorporate MOSFETs 200, 900, and/or 1000 in accordance with the present disclosure may also be provided to timing and noise characterization block 1906. The timing and noise characterization block 1906 may provide timing and noise characterizations of the integrated circuit design to logic synthesizer module 1802 at logic synthesizer process block 1910. Characterizations of the laid-out standard cells and the laid-out multi-bit cells (including MOSFETs 200, 900, and/or 1000) may also be provided to logic synthesizer module 1802 at logic synthesizer process block 1910. The digital RTL behavioral models of block 1908 may be among the RTL circuit description 1801 provided to logical synthesizer processor block 1910. RTL behavioral models of block 1908 may include but are not limited to digital signal processing (DSP) cores, peripheral blocks, and other blocks that may be digitally designed. Furthermore, the design constraints of block 1916, that may include, without limitation, various parameters for characterizing MOSFETs 200, 900, and/or 1000, may also be provided to logic synthesizer process block 1910. Within logic synthesizer process block 1910, logic synthesizer 1802 synthesizes the data and information relating to the laid-out standard cells, the laid-out multi-bit cells, the timing and noise characterizations, the various digital RTL behavioral models, and the design constraints to provide a physical design layout that results in an RTL to Graphic Data System (“GDS”) digital design implementation at block 1912. GDS is a format that may be used to control integrated circuit photomask plotting. The RTL-to-GDS digital design implementation includes at least the timing information and noise sign-off information. The GDS file containing the physical design layout information may be sent to a foundry for generation of a mask and the semiconductor chip at block 1914.

One of skill in the art will recognize that one or more of MOSFETs 200, 900, and/or 1000 may be integral to an integrated circuit or semiconductor chip.

As used herein, when two or more elements are referred to as “coupled” to one another, such term indicates that such two or more elements are in electronic communication or mechanical communication, as applicable, whether connected indirectly or directly, with or without intervening elements.

This disclosure encompasses all changes, substitutions, variations, alterations, and modifications to the example embodiments herein that a person having ordinary skill in the art would comprehend. Similarly, where appropriate, the appended claims encompass all changes, substitutions, variations, alterations, and modifications to the example embodiments herein that a person having ordinary skill in the art would comprehend. Moreover, reference in the appended claims to an apparatus or system or a component of an apparatus or system being adapted to, arranged to, capable of, configured to, enabled to, operable to, or operative to perform a particular function encompasses that apparatus, system, or component, whether or not it or that particular function is activated, turned on, or unlocked, as long as that apparatus, system, or component is so adapted, arranged, capable, configured, enabled, operable, or operative. Accordingly, modifications, additions, or omissions may be made to the systems, apparatuses, and methods described herein without departing from the scope of the disclosure. For example, the components of the systems and apparatuses may be integrated or separated. Moreover, the operations of the systems and apparatuses disclosed herein may be performed by more, fewer, or other components and the methods described may include more, fewer, or other steps. Additionally, steps may be performed in any suitable order. As used in this document, “each” refers to each member of a set or each member of a subset of a set.

Although exemplary embodiments are illustrated in the figures and described below, the principles of the present disclosure may be implemented using any number of techniques, whether currently known or not. The present disclosure should in no way be limited to the exemplary implementations and techniques illustrated in the drawings and described above.

Unless otherwise specifically noted, articles depicted in the drawings are not necessarily drawn to scale.

All examples and conditional language recited herein are intended for pedagogical objects to aid the reader in understanding the disclosure and the concepts contributed by the inventor to furthering the art, and are construed as being without limitation to such specifically recited examples and conditions. Although embodiments of the present disclosure have been described in detail, it should be understood that various changes, substitutions, and alterations could be made hereto without departing from the spirit and scope of the disclosure.

Although specific advantages have been enumerated above, various embodiments may include some, none, or all of the enumerated advantages. Additionally, other technical advantages may become readily apparent to one of ordinary skill in the art after review of the foregoing figures and description.

To aid the Patent Office and any readers of any patent issued on this application in interpreting the claims appended hereto, applicants wish to note that they do not intend any of the appended claims or claim elements to invoke 35 U.S.C. § 112(f) unless the words “means for” or “step for” are explicitly used in the particular claim.

What is claimed is:

1. A semiconductor structure comprising:
a substrate;
an active region formed on the substrate;
a gate region extended over the active region along a first direction parallel to a surface of the substrate; and
a source region formed within the active region and adjacent to the gate region in a second direction parallel to the surface and perpendicular to the first direction, wherein:
the source region comprises a first subregion and a second subregion such that the second subregion is between the first subregion and the gate region;
the first subregion comprises a first width along the first direction and the second subregion comprises a second width along the first direction; and
the first width is less than the second width.

2. The semiconductor structure of claim 1, further comprising a channel region formed in the active region between the subtsrate and the gate region, wherein:
the channel region has a channel width along the first direction; and
the channel width is substantially equal to the second width.

3. The semiconductor structure of claim 1, wherein:
the second subregion comprises a length along the second direction;
the second subregion extends beyond the first subregion by a third width along the first direction; and
the length is less than or equal to the third width.

4. The semiconductor structure of claim 1, wherein:
the first subregion comprises a first length along the second direction;
the second subregion comprises a second length along the second direction; and
the second length is less than the first length.

5. The semiconductor structure of claim 1, wherein:
the first subregion comprises a first length along the second direction;
the second subregion comprises a second length along the second direction; and
wherein a first ratio of the first length to the first width is less than or equal to a second ratio of the second width to the second length.

6. The semiconductor structure of claim 1, further comprising a drain region formed in the active structure and adjacent to the gate region in the second direction, wherein:
the gate region is between the source region and the drain region;
the drain region comprises a third subregion and a fourth subregion;
the fourth subregion is between the third subregion and the gate region;
the third subregion comprises a third width along the first direction and the fourth subregion comprises a fourth width along the first direction; and
the third width is less than the fourth width.

7. The semiconductor structure of claim 1, wherein:
a first portion of the gate structure has a first doping and a second portion of the gate structure has a second doping; and
the first doping is different from the second doping.

8. The semiconductor structure of claim 1, wherein:
the source region further comprises a third subregion;
wherein the third subregion is between the first subregion and the second subregion;
the first subregion comprises a first width along the first direction and the second subregion comprises a second width along the first direction and the third subregion comprises a third width along the first direction; and
the first width is less than the third width and the third width is less than the second width.

9. The semiconductor structure of claim 8 wherein at least one of the first subregion and the third subregion form a tapered shape in which width of such region varies in the first direction.

10. An integrated circuit comprising:
a substrate; and
a transistor over the substrate comprising:
an active region formed on the substrate;
a gate region extended over the active region along a first direction parallel to a surface of the substrate; and
a source region formed within the active region and adjacent to the gate region in a second direction parallel to the surface and perpendicular to the first direction, wherein:
the source region comprises a first subregion and a second subregion such that the second subregion is between the first subregion and the gate region;
the first subregion comprises a first width along the first direction and the second subregion comprises a second width along the first direction; and
the first width is less than the second width.

11. The integrated circuit of claim 10, wherein the transistor further comprises a channel region formed in the active region, wherein:
the channel region has a channel width along the first direction; and
the channel width is substantially equal to the second width.

12. The integrated circuit of claim 10, wherein:
the second subregion comprises a length along the second direction;
the second subregion extends beyond the first subregion by a third width along the first direction; and
the length is less than or equal to the third width.

13. The integrated circuit of claim 10, wherein:
the first subregion comprises a first length along the second direction;
the second subregion comprises a second length along the second direction; and
the second length is less than the first length.

14. The integrated circuit of claim 10, wherein:
the first subregion comprises a first length along the second direction;
the second subregion comprises a second length along the second direction; and
wherein a first ratio of the first length to the first width is less than or equal to a second ratio of the second width to the second length.

15. The integrated circuit of claim 10, wherein the transistor further comprises a drain region formed in the active region and adjacent to the gate region in the second direction, wherein:
the gate region is between the source region and the drain region;
the drain region comprises a third subregion and a fourth subregion;
the fourth subregion is between the third subregion and the gate region;
the third subregion comprises a third width along the first direction and the fourth subregion comprises a fourth width along the first direction; and
the third width is less than the fourth width.

16. The integrated circuit of claim 10, wherein:
a first portion of the gate region has a first doping and a second portion of the gate region has a second doping; and
the first doping is different from the second doping.

17. The integrated circuit of claim 10, wherein:
the source region further comprises a third subregion;
wherein the third subregion is between the first subregion and the second subregion;
the first subregion comprises a first width along the first direction and the second subregion comprises a second width along the first direction and the third subregion comprises a third width along the first direction; and
the first width is less than the third width and the third width is less than the second width.

18. The integrated circuit of claim 17 wherein at least one of the first subregion and the third subregion form a tapered shape in which width of such region varies in the first direction.

19. A semiconductor chip, comprising:
a substrate;
a first active region having a first width along a first direction parallel to a surface of the substrate;
a gate extended over the first active region along the first direction; and
a second active region formed on the surface adjacent to a first oxide diffusion region and having a second width shorter than the first width along the first direction.

20. The semiconductor chip of claim 19, further comprising a channel region formed in the first active region between the surface and the gate, wherein:
the channel region has a channel width along the first direction; and
the channel width is substantially equal to the first width.

21. The semiconductor chip of claim 19, wherein:
the first active region comprises a length along a second direction;
the first active region extends beyond the second active region by a third width along the first direction; and
the length is less than or equal to the third width.

22. The semiconductor chip of claim 19, wherein:
the first active region comprises a first length along a second direction;
the second active region comprises a second length along the second direction; and
the first length is less than the second length.

23. The semiconductor chip of claim 19, wherein:
the first oxide diffusion region comprises a first length along a second direction;
a second oxide diffusion region comprises a second length along the second direction; and
wherein a first ratio of the first length to the first width is greater than or equal to a second ratio of the second width to the second length.

24. The semiconductor chip of claim 23, further comprising a third oxide diffusion region formed on the surface adjacent to the second oxide diffusion region and having a third width shorter than the second width along the first direction.

25. The semiconductor chip of claim 24, wherein at least one of the second oxide diffusion region and the third oxide diffusion region form a tapered shape in which width of such region varies in the first direction.

26. A method comprising:
forming an active region on a substrate;
forming a gate region extended over the active region along a first direction parallel to a surface of the substrate; and
forming a source region within the active region and adjacent to the gate region in a second direction parallel to the surface and perpendicular to the first direction, wherein:
the source region comprises a first subregion and a second subregion such that the second subregion is between the first subregion and the gate region;
the first subregion comprises a first width along the first direction and the second subregion comprises a second width along the first direction; and
the first width is less than the second width.

27. The method of claim 26, further forming a channel region in the active region between the substrate and the gate region, wherein:
the channel region has a channel width along the first direction; and
the channel width is substantially equal to the second width.

28. The method of claim 26, wherein:
the second subregion comprises a length along the second direction;
the second subregion extends beyond the first subregion by a third width along the first direction; and
the length is less than or equal to the third width.

29. The method of claim 26, wherein:
the first subregion comprises a first length along the second direction;
the second subregion comprises a second length along the second direction; and
the second length is less than the first length.

30. The method of claim 26, wherein:
the first subregion comprises a first length along the second direction;
the second subregion comprises a second length along the second direction; and
wherein a first ratio of the first length to the first width is less than or equal to a second ratio of the second width to the second length.

31. The method of claim 26, further comprising forming a drain region in the active region and adjacent to the gate region in the second direction, wherein:
the gate region is between the source region and the drain region;
the drain region comprises a third subregion and a fourth subregion;
the fourth subregion is between the third subregion and the gate region;
the third subregion comprises a third width along the first direction and the fourth subregion comprises a fourth width along the first direction; and
the third width is less than the fourth width.

32. The method of claim 26, wherein:
a first portion of the gate region has a first doping and a second portion of the gate region has a second doping; and
the first doping is different from the second doping.

33. The method of claim 26, wherein:
the source region further comprises a third subregion;
wherein the third subregion is between the first subregion and the second subregion;
the first subregion comprises a first width along the first direction and the second subregion comprises a second width along the first direction and the third subregion comprises a third width along the first direction; and
the first width is less than the third width and the third width is less than the second width.

34. The method of claim 33 wherein at least one of the first subregion and the third subregion form a tapered shape in which width of such region varies in the first direction.

35. A computer program product for implementing a semiconductor structure comprising a substrate, an active region formed on the substrate, a gate region extended over the active region along a first direction parallel to a surface of the substrate, and a source region formed within the active region and adjacent to the gate region in a second direction parallel to the surface and perpendicular to the first direction, wherein the source region comprises a first subregion and a second subregion such that the second subregion is between the first subregion and the gate region, the first subregion comprises a first width along the first direction and the second subregion comprises a second width along the first direction, and the first width is less than the second width, the computer program product comprising a computer usable medium having computer readable code physically embodied therein, said computer program product further comprising computer readable program code for describing the semiconductor structure.
